(19) United States
(12) Patent Application Publication
(10) Pub. No.: US 2015/0171277 A1
(43) Pub. Date: Jun. 18, 2015

(54) LIGHT EMITTING DEVICE

(71) Applicant: Kabushiki Kaisha Toshiba, Minato-ku (JP)

(72) Inventor: Shinji SAITO, Yokohama (JP)

(73) Assignee: Kabushiki Kaisha Toshiba, Minato-ku (JP)

(21) Appl. No.: 14/567,297

(22) Filed: Dec. 11, 2014

(30) Foreign Application Priority Data
Dec. 18, 2013 (JP) 2013-261261

(51) Int. Cl. H01L 33/44; H01L 33/60; H01L 33/50

(52) U.S. Cl. CPC H01L 33/44; H01L 33/50; H01L 33/60

(57) ABSTRACT

According to one embodiment, a light emitting device includes a light emitting unit, a first wavelength selection layer, and a wavelength conversion layer. The light emitting unit emits a first light having a first peak wavelength. The first wavelength selection layer is transmissive to the first light. The first wavelength selection layer has a first reflectance with respect to the first peak wavelength. The wavelength conversion layer absorbs at least a portion of the first light passed through the first wavelength selection layer. The wavelength conversion layer emits a second light having a second peak wavelength longer than the first peak wavelength. The first wavelength selection layer has a second reflectance with respect to the second peak wavelength. The second reflectance is higher than the first reflectance.

### CROSS-REFERENCE TO RELATED APPLICATIONS

This application is based upon and claims the benefit of priority from Japanese Patent Application No. 2013-261261, filed on Dec. 18, 2013; the entire contents of which are incorporated herein by reference.

### FIELD

Embodiments described herein relate generally to a light emitting device.

### BACKGROUND

For example, semiconductor light emitting elements include light emitting diodes (LEDs). For example, such semiconductor light emitting elements include nitride semiconductors. For example, display devices, illumination, etc., include light emitting devices in which fluorescers and semiconductor light emitting elements are combined. Higher efficiency is desirable for such light emitting devices.

### BRIEF DESCRIPTION OF THE DRAWINGS

FIG. 1A and FIG. 1B are schematic cross-sectional views showing a light emitting device according to a first embodiment;

FIG. 2 is a schematic view showing the light emitting device according to the first embodiment;

FIG. 3 is a schematic view showing a light emitting device of a reference example;

FIG. 4 is a graph of characteristics of the light emitting device;

FIG. 5 is a schematic cross-sectional view showing a light emitting device according to a second embodiment;

FIG. 6 is a schematic view showing the light emitting device according to the second embodiment;

FIG. 7 is a schematic view showing a light emitting device of a reference example;

FIG. 8 is a schematic cross-sectional view showing a light emitting device according to the second embodiment;

FIG. 9 is a schematic cross-sectional view showing a light emitting device according to the second embodiment;

FIG. 10 is a schematic cross-sectional view showing a light emitting device according to the second embodiment; and

FIG. 11A to FIG. 11E are schematic views showing light emitting devices.

### DETAILED DESCRIPTION

According to one embodiment, a light emitting device includes a light emitting unit, a first wavelength selection layer, and a wavelength conversion layer. The light emitting unit emits a first light having a first peak wavelength. The first wavelength selection layer is transmissive to the first light. The first wavelength selection layer has a first reflectance with respect to the first peak wavelength. The wavelength conversion layer absorbs at least a portion of the first light passed through the first wavelength selection layer. The wavelength conversion layer emits a second light having a second peak wavelength longer than the first peak wavelength. The first wavelength selection layer has a second reflectance with respect to the second peak wavelength. The second reflectance is higher than the first reflectance.

Various embodiments will be described hereinafter with reference to the accompanying drawings.

The drawings are schematic or conceptual; and the relationships between the thicknesses and widths of portions, the proportions of sizes between portions, etc., are not necessarily the same as the actual values thereof. Further, the dimensions and/or the proportions may be illustrated differently between the drawings, even for identical portions.

In the drawings and the specification of the application, components similar to those described in regard to a drawing thereinabove are marked with like reference numerals, and a detailed description is omitted as appropriate.

### First Embodiment

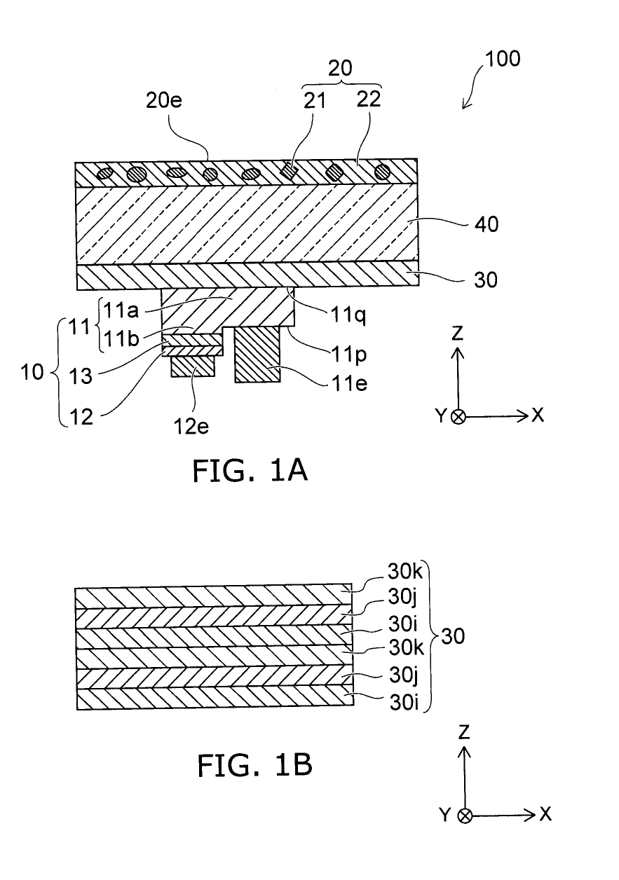

FIG. 1A and FIG. 1B are schematic cross-sectional views illustrating a light emitting device according to a first embodiment.

As shown in FIG. 1A, a light emitting device 100 includes a light emitting unit 10, a wavelength conversion layer 20, and a first wavelength selection layer 30. In the example, the light emitting device 100 further includes a substrate 40.

The first wavelength selection layer 30 is provided between the light emitting unit 10 and the wavelength conversion layer 20.

The light emitting unit 10 is, for example, a semiconductor light emitting element that uses a nitride semiconductor. For example, a light emitting diode (LED) is used as the light emitting unit 10. In the example, a flip chip-type LED is used as the light emitting unit 10.

The substrate 40 is provided between the first wavelength selection layer 30 and the wavelength conversion layer 20. The substrate 40 is light-transmissive. For example, a ceramic having high thermal conduction is used as the substrate 40. For example, a sapphire substrate is used as the substrate 40.

The direction from the light emitting unit 10 toward the wavelength conversion layer 20 is taken as a Z-axis direction. One direction perpendicular to the Z-axis direction is taken as an X-axis direction. A direction perpendicular to the X-axis direction and perpendicular to the Z-axis direction is taken as a Y-axis direction.

For example, a first semiconductor layer 11 of a first conductivity type, a second semiconductor layer 12 of a second conductivity type, and a light emitting layer 13 are provided in the light emitting unit 10. For example, the first conductivity type is an n-type; and the second conductivity type is a p-type. A first semiconductor portion 11a and a second semiconductor portion 11b are provided in the first semiconductor layer 11. The second semiconductor portion 11b is, for example, arranged with the first semiconductor portion 11a in the X-axis direction. The second semiconductor portion 11b is disposed between the second semiconductor layer 12 and the first wavelength selection layer 30. The light emitting layer 13 is provided between the second semiconductor portion 11b and the second semiconductor layer 12.

The first semiconductor layer 11 has a first major surface 11p and a second major surface 11q. The first major surface 11p is, for example, the surface on the light emitting layer 13 side. The second major surface 11q is the surface on the side opposite to the first major surface 11p. The second major surface 11q is the surface on the first wavelength selection layer 30 side.

For example, a first electrode 11e and a second electrode 12e are provided in the light emitting unit 10. A portion of the first semiconductor layer 11 on the first major surface 11p side is exposed at the first semiconductor portion 11a. The exposed portion of the first semiconductor layer 11 is electrically connected to the first electrode 11e. The second electrode 12e is electrically connected to the second semiconductor layer 12.

The first semiconductor layer 11 includes, for example, GaN doped with Si. The light emitting layer 13 has, for example, a quantum well structure in which a barrier layer and a well layer are stacked alternately. The barrier layer includes, for example, GaN; and the well layer includes, for example, InGaN. The second semiconductor layer 12 includes, for example, GaN doped with Mg. The configuration recited above is an example; and in the embodiment, the light emitting unit is not limited to the LED recited above. Various modifications of the configuration, materials, etc., of the light emitting unit 10 are possible.

In the light emitting unit 10, a current is supplied to the light emitting layer 13 via the first electrode 11e and the second electrode 12e; and a first light is emitted from the light emitting unit 10. The first light has a first peak wavelength. For example, the peak wavelength (the first peak wavelength) of the first light is 500 nanometers or less (nm). For example, the light emitting unit 10 includes a blue LED, a bluish-violet LED, a violet LED, an ultraviolet LED, etc. For example, the light emission wavelength (the wavelength of the first light) of the blue LED is 430 nm to 475 nm. For example, the peak wavelength of the first light is 450 nm.

For example, the wavelength conversion layer 20 includes wavelength conversion particles 21 and a resin 22 in which the wavelength conversion particles 21 are dispersed. The wavelength conversion particles 21 absorb at least a portion of the first light and emit a second light. The second light has a second peak wavelength.

The wavelength of the second light is longer than the wavelength of the first light. The wavelength band of the second light is longer than the wavelength band of the first light. For example, the shortest wavelength of the wavelength band of the second light is longer than the shortest wavelength of the wavelength band of the first light. For example, the longest wavelength of the wavelength band of the second light is longer than the longest wavelength of the wavelength band of the first light. For example, the shortest wavelength of the wavelength band of the second light is longer than the longest wavelength of the wavelength band of the first light. For example, the peak wavelength (the second peak wavelength) of the second light is longer than the peak wavelength of the first light.

For example, a fine particle of a fluorescer, a fine particle of a nitride semiconductor, etc., is used as the wavelength conversion particle 21. For example, AlₓGa_{y}In_{1-x-y}N (0≦x≦1, 0≦y≦1, and 0≦x+y≦1) is used as the nitride semiconductor. In such a nitride semiconductor, the wavelength of the light that is emitted can be changed by changing the values of x and y recited above. In the nitride semiconductor of the wavelength conversion particle 21, a portion of the Group III elements may be replaced with B, Tl, etc. In the nitride semiconductor of the wavelength conversion particle 21, a portion of N may be replaced with P, As, Sb, Bi, etc. The wavelength conversion particle 21 is not limited to one type of material and may include two or more types of materials.

For example, the wavelength conversion particle 21 may include one selected from a red fluorescer, a yellow fluorescer, a green fluorescer and a blue fluorescer.

The red fluorescer emits, for example, light in a wavelength region of 600 nm to 780 nm. The yellow fluorescer emits, for example, light in a wavelength region of 550 nm to 590 nm. The green fluorescer emits, for example, light in a wavelength region of 475 nm to 520 nm. The blue fluorescer emits light in a wavelength region of 430 nm to 475 nm.

The wavelength conversion layer 20 may have a multilayered structure. The wavelength conversion layer 20 may include multiple layers having different light emission wavelengths. In the embodiment, light emission characteristics such as the wavelengths, etc., of the first light and the second light are set appropriately based on the specifications of the light emitted by the light emitting device 100, etc. For example, the peak wavelength of the second light is 500 nm or more. The resin 22 includes, for example, a silicone-based resin, etc.

The wavelength conversion layer 20 has, for example, a light extraction surface 20e. The light extraction surface 20e is the surface of the wavelength conversion layer 20 on the side opposite to the substrate 40.

The first wavelength selection layer 30 is, for example, a dielectric multilayer film. For example, multiple films having different refractive indexes are stacked in the first wavelength selection layer 30. For example, the first wavelength selection layer 30 is formed by the multiple films being stacked in order on the substrate 40.

FIG. 1B is a schematic view showing the first wavelength selection layer 30.

The first wavelength selection layer 30 includes multiple first optical layers 30i and multiple second optical layers 30j. As shown in FIG. 1B, the multiple first optical layers 30i, the multiple second optical layers 30j, and multiple third optical layers 30k are stacked alternately in the Z-axis direction.

For example, an oxide layer including at least one selected from Si, Ta, Hf, Zr and Mg or a nitride layer including at least one selected from Si, Ta, Hf, Zr and Mg is used as the first optical layer 30i.

For example, an oxide layer including at least one selected from Si, Ta, Hf, Zr and Mg or a nitride layer including at least one selected from Si, Ta, Hf, Zr and Mg is used as the second optical layer 30j.

The refractive indexes of the first optical layers 30i are different from the refractive indexes of the second optical layers 30j. The refractive indexes of the first optical layers 30i are different from the refractive indexes of the third optical layers 30k. The refractive indexes of the second optical layers 30j are different from the refractive indexes of the third optical layers 30k. The thickness of each of the first optical layers 30i is, for example, not less than 30 nm and not more than 200 nm. The thickness of each of the second optical layers 30j is, for example, not less than 30 nm and not more than 200 nm. The thickness of each of the third optical layers 30k is, for example, not less than 30 nm and not more than 200 nm. The refractive indexes of the first to third optical layers 30i to 30k and the thicknesses of the first to third optical layers 30i to 30k are appropriately designed optically to match the wavelengths to be transmitted and the wavelengths to be reflected.

The first wavelength selection layer 30 is, for example, transmissive to the first light and reflective to the second light. The substrate 40 is transmissive to the first light and the second light. The transmittance of the first wavelength selection layer 30 for the peak wavelength of the first light is higher than the transmittance of the first wavelength selection layer 30 for the peak wavelength of the second light. The reflectance of the first wavelength selection layer 30 to the peak wavelength of the second light is higher than the reflectance of the first wavelength selection layer 30 to the peak wavelength of the first light.

A member that is transmissive has a transmittance that is higher than the reflectance and higher than the absorptance. For example, the member that is transmissive has a light transmittance that is, for example, 90% or more. The transmittance may be, for example, 80% or more.

A member that is reflective has a reflectance that is higher than the transmittance. For example, the reflectance is higher than the absorptance. For example, the member that is reflective has a reflectance that is, for example, 90% or more. The reflectance may be 80% or more.

For example, the first wavelength selection layer 30 has a transmittance that is 60% or more for the peak wavelength of the first light. For example, the first wavelength selection layer has a reflectance that is 60% or more for the peak wavelength of the second light.

For example, the transmittance of the first wavelength selection layer 30 for the first light is higher than the transmittance of the substrate 40 for the first light. For example, the reflectance of the first wavelength selection layer 30 to the second light is higher than the reflectance of the substrate 40 to the second light.

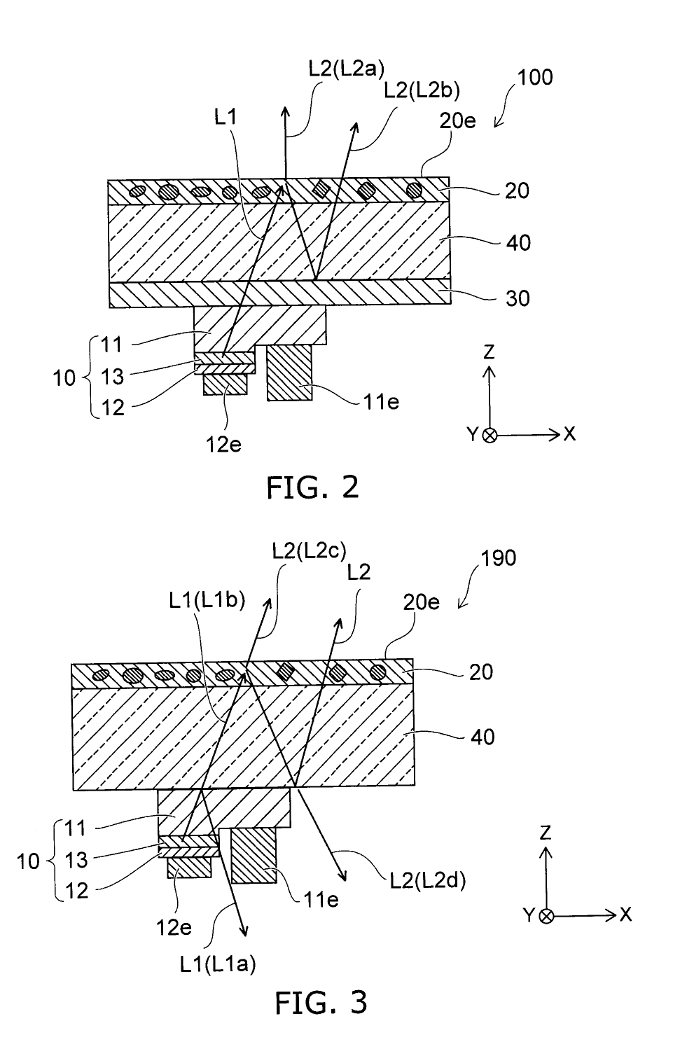

FIG. 2 is a schematic view illustrating the light emitting device according to the first embodiment.

FIG. 2 shows an operation of the light emitting device 100.

For example, light is emitted from the light emitting layer 13 when a current is supplied to the light emitting unit 10. In other words, the light emitting layer 13 emits a first light L1. A portion of the first light L1 travels toward the first wavelength selection layer 30.

The first wavelength selection layer 30 is transmissive to the first light L1. A portion of the first light L1 that is incident on the first wavelength selection layer 30 propagates through the first wavelength selection layer 30 and through the substrate 40 and is incident on the wavelength conversion layer 20.

A portion of the first light L1 that is incident on the wavelength conversion layer 20 is absorbed by the wavelength conversion particles 21 in the wavelength conversion layer 20. In the wavelength conversion, the portion of the first light L1 is absorbed and a second light L2 is emitted.

A portion (L2a) of the second light L2 travels toward the light extraction surface 20e and is extracted to the external environment. Another portion (L2b) of the second light L2 travels in the reverse direction of the direction toward the light extraction surface 20e, propagates through the substrate 40, and reaches the first wavelength selection layer 30. A portion of the second light L2 that reaches the first wavelength selection layer 30 is reflected by the first wavelength selection layer 30. A portion of the second light L2 that is reflected propagates through the substrate 40 and through the wavelength conversion layer 20, travels toward the light extraction surface 20e, and is extracted to the external environment.

FIG. 3 is a schematic view illustrating a light emitting device of a reference example.

The light emitting unit 10, the wavelength conversion layer 20, and the substrate 40 are provided in the light emitting device 190 shown in FIG. 3 as well. The configuration described in regard to the light emitting device 100 is applicable to these components. The first wavelength selection layer 30 is not provided in the light emitting device 190. The light emitting device 190 corresponds to a configuration in which the first wavelength selection layer 30 of the light emitting device 100 is omitted.

In the light emitting device 190 as well, the first light L1 is emitted from the light emitting layer 13. A portion of the first light L1 travels toward the substrate 40. A portion (L1a) of the light that reaches the substrate 40 is reflected by the substrate 40 and travels in the reverse direction of the direction toward the light extraction surface 20e. The light that is reflected by the substrate 40 is lost.

Conversely, in the light emitting device 100, the first wavelength selection layer 30 that is transmissive to the first light L1 is provided. A portion of the first light L1 that reaches the first wavelength selection layer 30 from the light emitting unit 10 is not easily reflected by the first wavelength selection layer 30 and propagates through the first wavelength selection layer 30. Thereby, the loss of the first light L1 is suppressed.

A portion of the first light L1 that propagates through the first wavelength selection layer 30 is incident on the substrate 40. To promote the first light L1 entering the interior of the substrate 40, it is desirable to appropriately set the refractive index (a first refractive index n1) of the portion of the light emitting unit 10 contacting the first wavelength selection layer 30, the refractive index (a second refractive index n2) of the portion of the first wavelength selection layer 30 contacting the substrate 40, and the refractive index (a third refractive index n3) of the substrate 40. For example, the difference between the second refractive index n2 and the third refractive index n3 is set to be smaller than the difference between the first refractive index n1 and the third refractive index n3. Thereby, the reflection (the Fresnel reflection) of the first light L1 by the substrate 40 can be suppressed more for the case where the first wavelength selection layer 30 is provided than for the case where the first wavelength selection layer 30 is not provided. Thereby, the loss of the first light L1 is suppressed.

In the light emitting device 190 of the reference example, another portion (L1b) of the first light L1 propagates through the substrate 40 and is incident on the wavelength conversion layer 20. A portion of the first light L1 that is incident on the wavelength conversion layer 20 is absorbed by the wavelength conversion particles 21 in the wavelength conversion layer 20. The wavelength conversion layer 20 that absorbs the portion of the first light L1 emits the second light L2. A portion (L2c) of the second light L2 that is emitted travels toward the light extraction surface 20e and is extracted to the external environment.

Another portion (L2d) of the second light L2 travels in the reverse direction of the direction toward the light extraction surface 20e and passes through the substrate 40. The light that passes through the substrate 40 is lost.

Conversely, in the light emitting device 100, the first wavelength selection layer 30 that is reflective to the second light L2 is provided. Thereby, the portion (L2b) of the second light L2 that propagates through the substrate 40 and reaches the first wavelength selection layer 30 is easily reflected by the first wavelength selection layer 30. A portion of the second light L2 that is reflected by the first wavelength selection layer 30 travels toward the light extraction surface 20e and is extracted to the external environment.

By providing the first wavelength selection layer 30 as in the light emitting device 100, the loss of the light can be suppressed; and the luminous efficiency increases.

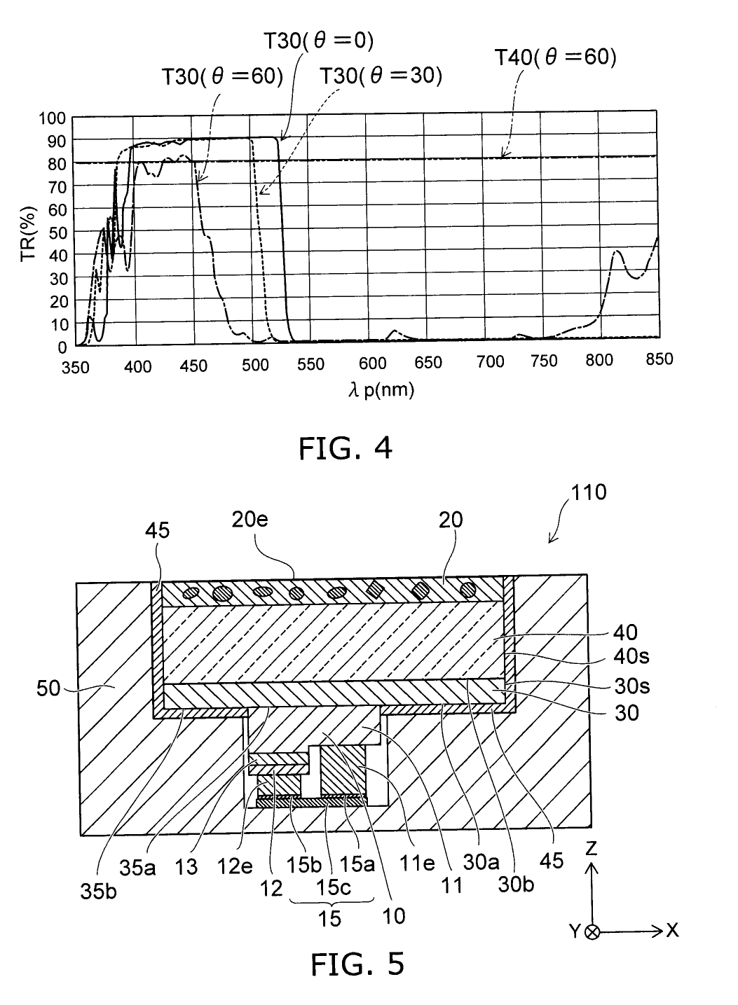

FIG. 4 is a graph of characteristics of the light emitting device.

In FIG. 4, the vertical axis is a light transmittance TR %; and the horizontal axis is an incident wavelength λp. FIG. 4 shows the light transmittance when light of the wavelength λp is incident at an incident angle θ. FIG. 4 shows data of the first wavelength selection layer 30 used in the light emitting device 100 and data of the sapphire substrate of the reference example.

As shown in FIG. 4, a light transmittance T40 of the sapphire substrate 40 of the reference example has little dependence on the wavelength λp. The sapphire substrate 40 has, for example, a relatively high transmittance T40 of about 80% from the region where the wavelength λp is short to the region where the wavelength λp is long (not less than 350 nm and not more than 850 nm). The second light L2 that is emitted from the wavelength conversion layer 20 and propagates through the substrate 40 easily passes through the substrate 40. The light that passes through the substrate 40 travels in the reverse direction of the light extraction surface 20e and is lost.

On the other hand, as shown in FIG. 4, a light transmittance T30 of the first wavelength selection layer 30 is dependent on the incident angle θ and the wavelength λp. The light transmittance T30 of the first wavelength selection layer 30 is, for example, 10% or less in the region where the wavelength λp is long (not less than 550 nm and not more than 750 nm). For example, in the case where a yellow second light L2 is used, a portion of the second light L2 that is emitted from the wavelength conversion layer 20 and propagates through the substrate 40 does not easily pass through the first wavelength selection layer 30. For example, the portion of the second light L2 is reflected by the first wavelength selection layer 30 and travels toward the light extraction surface 20e. Thereby, the loss of the second light L2 can be suppressed.

For light having an incident angle θ of 0 degrees or 30 degrees, the first wavelength selection layer 30 has a high transmittance T30 of about 90% in the region where the wavelength λp is short (not less than 400 nm and not more than 500 nm). For light having an incident angle θ of 60 degrees as well, the first wavelength selection layer 30 has a transmittance T30 of about 80% in the region where the wavelength is short (not less than 400 and not more than 450 nm). For example, in the case where the light emitting unit 10 includes a blue LED, the first light L1 that is emitted from the light emitting unit 10 and is incident on the first wavelength selection layer 30 is not easily reflected by the first wavelength selection layer 30. The first light L1 passes through the first wavelength selection layer 30 and is incident on the substrate 40. For example, by providing the first wavelength selection layer 30, the reflection of the first light L1 is suppressed by the substrate 40. Thereby, the loss of the first light L1 can be suppressed.

By providing the first wavelength selection layer 30, a light emitting device is provided in which the loss of the light is suppressed and the luminous efficiency is higher. According to the embodiment, a highly efficient light emitting device can be provided.

### Second Embodiment

FIG. 5 is a schematic cross-sectional view illustrating a light emitting device according to a second embodiment. The light emitting device 110 includes the light emitting unit 10, the wavelength conversion layer 20, the first wavelength selection layer 30, and the substrate 40. The configuration described in regard to the light emitting device 100 is applicable to these components. The light emitting device 110 further includes a reflective metal film 45 and a mounting member 50.

The first wavelength selection layer 30 has a first surface 30a and a second surface 30b. The second surface 30b is separated from the first surface 30a in the Z-axis direction. The first surface 30a is the surface on the light emitting unit 10 side. The first surface 30a is the surface on the side opposite to the substrate 40. The second surface 30b is the surface on the substrate 40 side.

The first surface 30a includes a first region 35a and a second region 35b. The first region 35a is the region that overlaps the light emitting unit 10 when projected onto a plane (e.g., the X-Y plane) intersecting the direction from the light emitting unit 10 toward the wavelength conversion layer 20. The second region 35b is the region that does not overlap the light emitting unit 10 when projected onto the plane (e.g., the X-Y plane) intersecting the direction from the light emitting unit 10 toward the wavelength conversion layer 20.

The first wavelength selection layer 30 has a first side surface 30s. The first side surface 30s is a surface that intersects the first surface 30a. The substrate 40 has a second side surface 40s. The second side surface 40s is a surface that intersects the plane (e.g., the X-Y plane) intersecting the direction from the light emitting unit 10 toward the wavelength conversion layer 20.

The reflective metal film 45 covers at least a portion of at least one selected from the second side surface 40s, the first side surface 30s and the second region 35b and contacts at least a portion of at least one selected from the second side surface 40s, the first side surface 30s and the second region 35b. In the example, the reflective metal film 45 covers the second side surface 40s, the first side surface 30s, and the second region 35b and contacts the second side surface 40s, the first side surface 30s, and the second region 35b. The reflective metal film 45 includes, for example, at least one selected from Al and Ag. The reflective metal film 45 is reflective to the first light and the second light.

For example, the light emitting unit 10 and the first wavelength selection layer 30 are disposed between the substrate 40 and the mounting member 50. For example, a mounting pattern 15 is provided on the surface of the mounting member 50 on the light emitting unit 10 side. The mounting pattern 15 includes a first connection member 15a, a second connection member 15b, and a mounting substrate 15c.

The first connection member 15a is disposed between the mounting substrate 15c and the first electrode 11e. The mounting substrate 15c is electrically connected to the first electrode 11e via the first connection member 15a.

The second connection member 15b is disposed between the mounting substrate 15c and the second electrode 12e. The mounting substrate 15c is electrically connected to the second electrode 12e via the second connection member 15b. The light emitting unit 10 is energized via the mounting pattern 15.

For example, the mounting member 50 is provided to cover at least a portion of at least one selected from the second side surface 40s, the first side surface 30s and the second region 35b. For example, the mounting member 50 contacts at least a portion of the reflective metal film 45. The mounting member 50 includes, for example, Al or Cu.

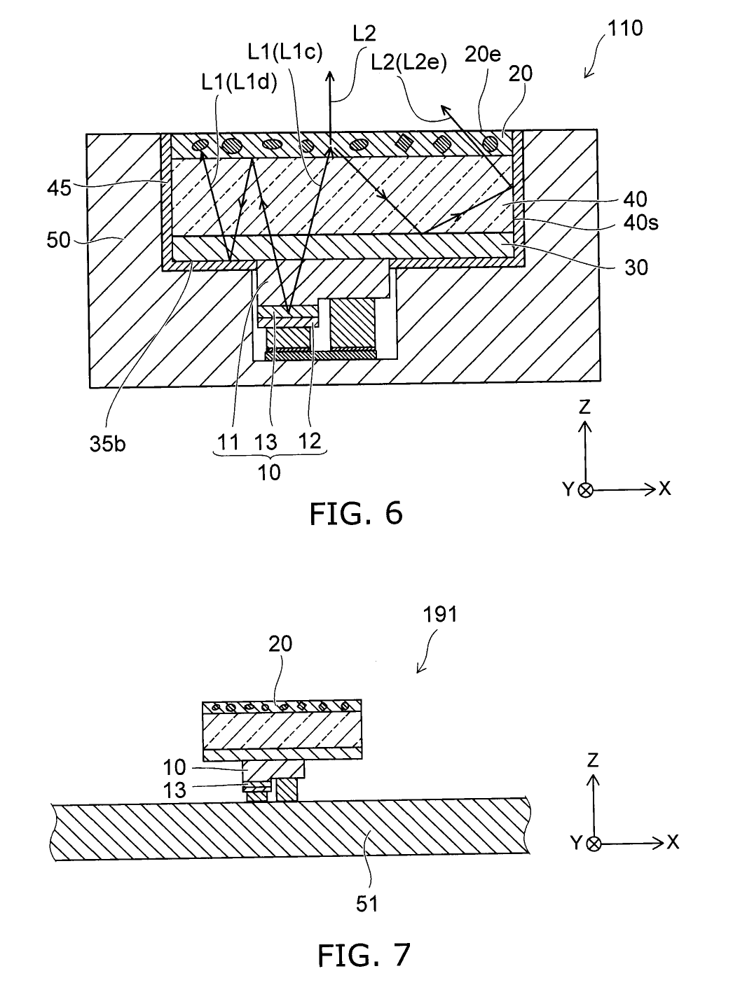

FIG. 6 is a schematic view illustrating the light emitting device according to the second embodiment. FIG. 6 shows an operation of the light emitting device 110.

As shown in FIG. 6, the light emitting layer 13 emits the first light L1 by the light emitting unit 10 being energized. A portion (L1c) of the first light L1 travels, for example, in the direction of the light extraction surface 20e. A portion of the first light L1 propagates through the first wavelength selection layer 30 and the substrate 40 and is incident on the wavelength conversion layer 20. A portion of the first light L1 that is incident on the wavelength conversion layer 20 is absorbed by the wavelength conversion particles 21. The wavelength conversion particles 21 emit the second light L2.

A portion (L2e) of the emitted second light L2 is emitted in the reverse direction of the direction toward the light extraction surface 20e. For example, a portion of the second light L2 that is emitted propagates through the substrate 40 and is reflected by the first wavelength selection layer 30. A portion of the second light L2 that is reflected by the first wavelength selection layer 30 travels, for example, toward the second side surface 40s. For example, the reflective metal film 45 is provided at the second side surface 40s. Thereby, for example, a portion of the second light L2 that travels toward the second side surface 40s is reflected by the reflective metal film 45. A portion of the second light L2 that is reflected travels, for example, toward the extraction surface 20e and is extracted to the external environment.

If the reflective metal film 45 is not provided, the portion of the second light L2 propagates through the substrate 40, travels toward the second side surface 40s, passes through the substrate 40, and travels in the direction in which the light extraction surface 20e is not provided. This light is lost.

For example, another portion (L1d) of the first light L1 that is emitted from the light emitting unit 10 propagates through the first wavelength selection layer 30 and the substrate 40 and reaches the wavelength conversion layer 20. A portion of the first light L1 that reaches the wavelength conversion layer 20 is reflected, for example, at the interface between the substrate 40 and the wavelength conversion layer 20. A portion of the first light L1 that is reflected travels, for example, in the reverse direction of the direction toward the light extraction surface 20e. A portion of the first light L1 propagates through the substrate 40 and through the first wavelength selection layer 30 and travels, for example, toward the second region 35b. For example, the reflective metal film 45 that contacts the second region 35b is provided. A portion of the first light L1 that travels toward the second region 35b is reflected by the reflective metal film 45 and again travels in the direction of the light extraction surface 20e.

If the reflective metal film 45 is not provided, a portion of the first light L1 that travels toward the second region 35b passes through the first wavelength selection layer 30 and travels in the direction in which the light extraction surface 20e is not provided. This light is lost.

By providing the reflective metal film 45 in the light emitting device 110 according to the embodiment, the loss of the light can be suppressed; and the luminous efficiency can be higher. According to investigations of the inventor of the application, it was discovered that the luminous efficiency of the light emitting device 110 was 1.7 times the luminous efficiency of the light emitting device 190 of the reference example when the electrical power of the light emitting unit 10 was set to 1.5 W.

FIG. 7 is a schematic view illustrating a light emitting device of a reference example.

As shown in FIG. 7, the light emitting unit 10, the wavelength conversion layer 20, and a mounting member 51 (a heat-dissipating substrate) are provided in the light emitting device 191 of the reference example. The light emitting unit 10 is provided between the wavelength conversion layer 20 and the mounting member 51. The configuration described in regard to the light emitting device 100 is applicable to the light emitting unit 10 and the wavelength conversion layer 20.

In the light emitting device 191, the first light is emitted from the light emitting unit 10. The first light is absorbed by the wavelength conversion particles 21 in the wavelength conversion layer 20. The wavelength conversion particles 21 emits the second light. In such a case, heat is generated in the wavelength conversion layer 20. The heat that is generated in the wavelength conversion layer 20 is conducted to the mounting member 51 via the light emitting unit 10 and is dissipated. When the second light is emitted in the wavelength conversion layer 20, the temperature of the light emitting unit increases easily. When the temperature of the light emitting unit 10 increases, there are cases where the luminous efficiency of the light emitting layer 13 decreases.

On the other hand, in the light emitting device 110 according to the embodiment, the substrate 40 is provided between the light emitting unit 10 and the wavelength conversion layer 20. The substrate 40 includes, for example, a ceramic having a high thermal conductivity. Further, the mounting member 50 that is provided in the light emitting device 110 contacts the reflective metal film 45 provided to cover the second side surface 40s, the first side surface 30s, and the second region 35b. Thereby, the heat that is generated in the wavelength conversion layer 20 is conducted to the mounting member 50 via the substrate 40 and the reflective metal film 45 and is dissipated efficiently.

According to investigations of the inventor of the application, the thermal resistance of the wavelength conversion layer 20 of the light emitting device 191 of the reference example is 1.06 K/W. The thermal resistance of the wavelength conversion layer 20 of the light emitting device 110 is 0.29 K/W. According to the embodiment, the heat dissipation is improved to about 3.65 times that of the light emitting device 191 of the reference example.

The heat dissipation of the light emitting device 110 does not easily occur via the light emitting unit 10 as does the heat dissipation of the light emitting device 191. Therefore, compared to the light emitting device 191, the temperature of the light emitting unit 10 does not easily increase and the luminous efficiency does not easily decrease in the light emitting device 110.

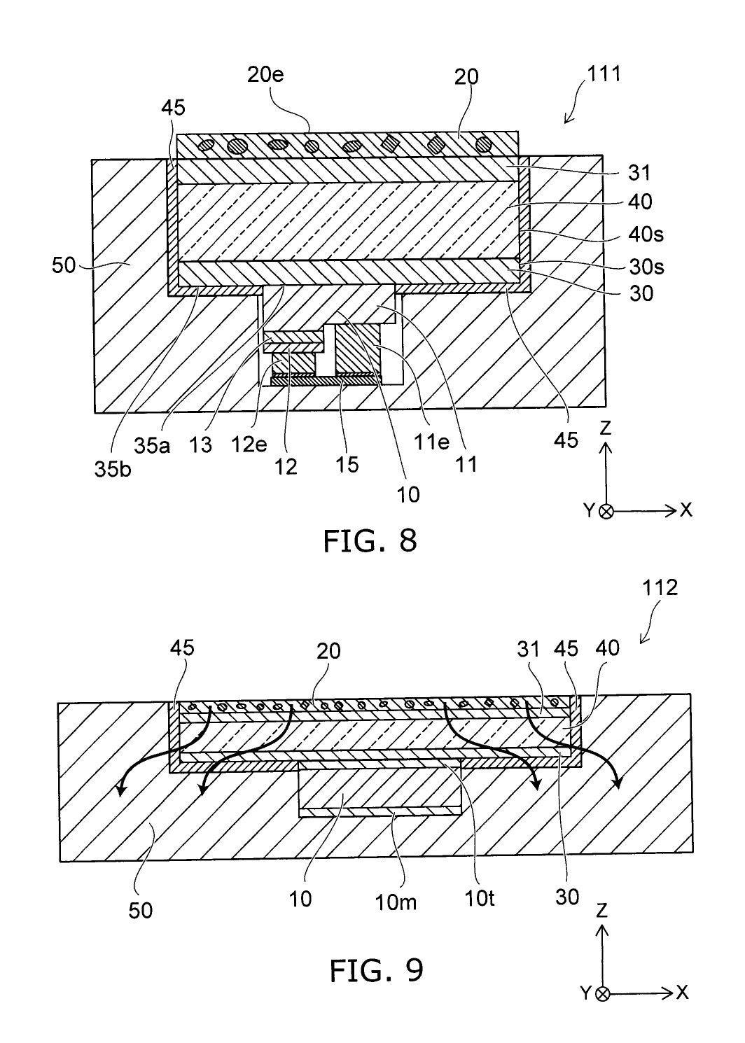

FIG. 8 is a schematic cross-sectional view illustrating a light emitting device according to the second embodiment.

As shown in FIG. 8, the light emitting device 111 includes the light emitting unit 10, the wavelength conversion layer 20, the first wavelength selection layer 30, the substrate 40, the reflective metal film 45, and the mounting member 50. The configuration described in regard to the light emitting device 110 is applicable to these components. The light emitting device 111 further includes a second wavelength selection layer 31. The second wavelength selection layer 31 is provided between the wavelength conversion layer 20 and the substrate 40. The light emitting device 111 corresponds to a configuration in which the second wavelength selection layer 31 is further provided in the light emitting device 110.

The second wavelength selection layer 31 is transmissive to the first light and reflective to the second light. The second wavelength selection layer 31 may have, for example, a configuration similar to that of the first wavelength selection layer 30.

For example, a portion of the first light that is emitted from the light emitting unit 10 propagates through the first wavelength selection layer 30 and through the substrate 40 and reaches the second wavelength selection layer 31. The second wavelength selection layer 31 is transmissive to the first light. Thereby, the portion of the first light that reaches the second wavelength selection layer 31 is not easily reflected by the second wavelength selection layer 31 and propagates through the second wavelength selection layer 31. Thereby, the incidence efficiency of the first light can be higher; and the luminous efficiency is higher.

A portion of the first light that propagates through the second wavelength selection layer 31 is incident on the wavelength conversion layer 20. To promote the first light entering the interior of the wavelength conversion layer 20, it is desirable to appropriately set the refractive index (the third refractive index n3) of the substrate 40, the refractive index (a fourth refractive index n4) of the portion of the second wavelength selection layer 31 contacting the wavelength conversion layer 20, and the refractive index (a fifth refractive index n5) of the wavelength conversion layer 20. For example, the difference between the fourth refractive index n4 and the fifth refractive index n5 is set to be smaller than the difference between the third refractive index n3 and the fifth refractive index n5. Thereby, the reflection (the Fresnel reflection) of the first light by the wavelength conversion layer 20 can be suppressed more for the case where the second wavelength selection layer 31 is provided than for the case where the second wavelength selection layer 31 is not provided. Thereby, the incidence efficiency of the first light on the wavelength conversion layer 20 can be higher; and the luminous efficiency of the light emitting device 111 increases.

FIG. 9 is a schematic cross-sectional view illustrating a light emitting device according to the second embodiment.

The light emitting unit 10, the wavelength conversion layer 20, the first wavelength selection layer 30, the second wavelength selection layer 31, the substrate 40, the reflective metal film 45, and the mounting member 50 are provided in the light emitting device 112 shown in FIG. 9 as well. The configuration described in regard to the light emitting device 111 is applicable to these components. For example, the light emitting unit 10 may be an LED including a transparent electrode 10t and a metal electrode 10m. For example, the transparent electrode 10t is provided on the surface of the light emitting unit 10 on the wavelength conversion layer 20 side. For example, the metal electrode 10m is provided on the surface of the light emitting unit 10 on the side opposite to the surface on the wavelength conversion layer 20 side. The light emitting unit 10 is, for example, a vertical-conduction LED in which the current flows along the Z-axis direction through the transparent electrode 10t and the metal electrode 10m.

For example, the wavelength conversion layer 20 absorbs at least a portion of the first light emitted from the light emitting unit 10 and emits the second light. The wavelength conversion layer 20 generates heat when emitting the second light. In the light emitting device 112, the heat that is generated in the wavelength conversion layer 20 is conducted, for example, via the second wavelength selection layer 31 to the substrate 40 having the high thermal conductivity. The heat that is conducted to the substrate 40 is conducted, for example, via the reflective metal film 45 to the mounting member 50. The reflective metal film 45 and the mounting member 50 include a metal; and the reflective metal film 45 and the mounting member 50 have high thermal conductivities. Thereby, for example, the heat that is generated in the wavelength conversion layer 20 is dissipated efficiently.

For example, the thickness of the substrate 40 is not less than 50 micrometers and not more than 1 millimeter. For example, the surface area of the substrate 40 is greater than the surface area of the light emitting unit 10 when projected onto the X-Y plane. For example, the surface area of the substrate 40 is not less than twice the surface area of the light emitting unit 10 when projected onto the X-Y plane. Thereby, the region of the substrate 40 that is covered with the mounting member 50 is wider. Thereby, for example, the heat that is conducted to the substrate 40 from the wavelength conversion layer 20 is dissipated efficiently to the mounting member 50. The decrease of the luminous efficiency can be suppressed.

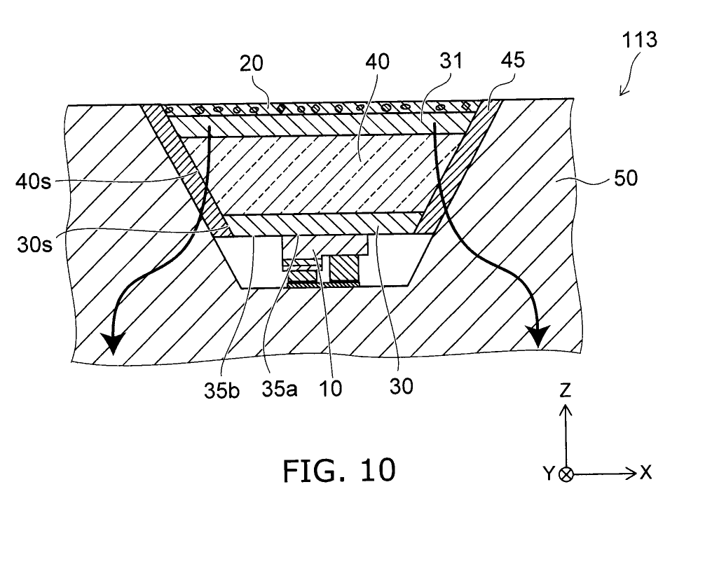

FIG. 10 is a schematic cross-sectional view illustrating a light emitting device according to the second embodiment.

The light emitting unit 10, the wavelength conversion layer 20, the first wavelength selection layer 30, the second wavelength selection layer 31, the substrate 40, the reflective metal film 45, and the mounting member 50 are provided in the light emitting device 113 shown in FIG. 10 as well.

The configuration described in regard to the light emitting device 110 is applicable to the wavelength conversion layer 20, the first wavelength selection layer 30, the substrate 40, the reflective metal film 45, and the mounting member 50.

In the example as shown in FIG. 10, the surface area of the first wavelength selection layer 30 is less than the surface area of the second wavelength selection layer 31 when projected onto the plane (e.g., the X-Y plane) intersecting the direction from the light emitting unit 10 toward the wavelength conversion layer 20. For example, the surface area of the surface of the substrate 40 on the wavelength conversion layer 20 side is greater than the surface area of the surface of the substrate 40 on the light emitting unit 10 side.

In the light emitting device 113 as well, similarly to the light emitting device 110, the loss of the light is suppressed; and the heat dissipation is improved. A light emitting device in which the luminous efficiency is higher is provided.

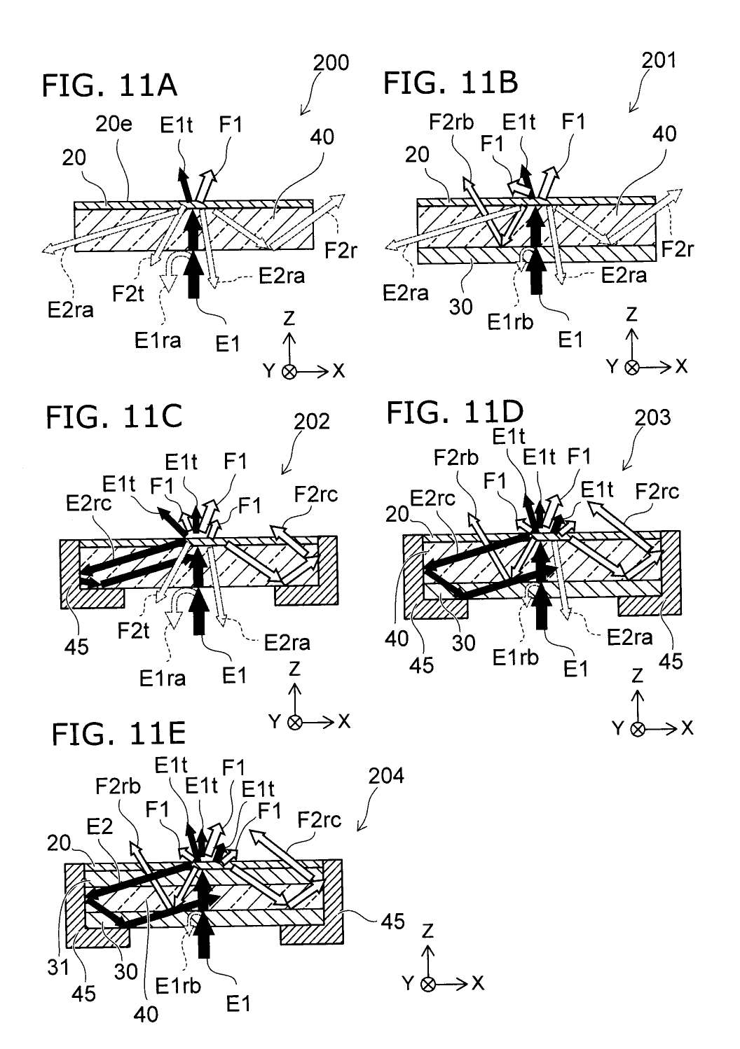

FIG. 11A to FIG. 11E are schematic views illustrating light emitting devices.

FIG. 11A is a schematic view showing a light emitting device 200 of a reference example. The light emitting unit 10 (not shown), the wavelength conversion layer 20, and the substrate 40 are provided in the light emitting device 200. The configuration described in regard to the light emitting device 100 is applicable to these components.

For example, an excitation light E1 is emitted from the light emitting unit 10. The excitation light E1 travels in the direction of the substrate 40 from the light emitting unit 10 and is incident on the substrate 40. A portion (a reflected excitation light E1ra) of the excitation light E1 is reflected by the substrate 40. Another portion of the excitation light E1 that is incident on the substrate 40 propagates through the substrate 40 and is incident on the wavelength conversion layer 20. A portion (a reflected excitation light E2ra) of the excitation light E1 that is incident on the wavelength conversion layer 20 is reflected by the wavelength conversion layer 20 and travels, for example, in the direction of the light emitting unit 10. A portion (a transmitted excitation light E1t) of the excitation light E1 that is incident on the wavelength conversion layer 20 passes through the wavelength conversion layer 20 and is extracted to the external environment. Another portion of the excitation light E1 that is incident on the wavelength conversion layer 20 is absorbed in the wavelength conversion layer 20. The wavelength conversion layer 20 emits fluorescence F1, fluorescence F2t, and fluorescence F2r. The fluorescence F1 travels in the direction of the surface of the wavelength conversion layer 20 on the side opposite to the surface opposing the substrate 40 and is extracted to the external environment. The fluorescence F2t and the fluorescence F2r travel in the direction from the wavelength conversion layer 20 toward the light emitting unit 10. For example, the fluorescence F2r propagates through the substrate 40 and undergoes total internal reflection at the surface of the substrate 40 on the light emitting unit 10 side. In the light emitting device 200, the reflected excitation light E1ra, the reflected excitation light E2ra, fluorescence F2, and the fluorescence F2r are lost; and the luminous efficiency of the light emitting device 200 decreases.

FIG. 11B is a schematic view showing a light emitting device 201 according to the embodiment. A light emitting unit (not shown), the wavelength conversion layer 20, the substrate 40, and the first wavelength selection layer 30 are provided in the light emitting device 201. The configuration described in regard to the light emitting device 100 is applicable to these components. The light emitting device 201 corresponds to a light emitting device in which the first wavelength selection layer 30 is provided in the light emitting device 200.

In the light emitting device 201 as well, the excitation light E1 is emitted from the light emitting unit 10. A portion of the excitation light E1 travels in the direction of the substrate 40 from the light emitting unit 10, travels through the first wavelength selection layer 30, and is incident on the substrate 40. A portion (a reflected excitation light E1rb) of the excitation light E1 that is incident on the substrate 40 is reflected by the substrate 40. Similarly to the description of the light emitting device 200, the transmitted excitation light E1t, the reflected excitation light E2ra, the fluorescence F1, and the fluorescence F2r are produced in the light emitting device 201 as well. In the light emitting device 201, fluorescence F2rb that is emitted from the wavelength conversion layer 20 travels in the direction from the wavelength conversion layer 20 toward the light emitting unit 10. The fluorescence F2rb that travels through the substrate 40 is reflected by the first wavelength selection layer 30, travels in the direction of the wavelength conversion layer 20 and is extracted to the external environment. In the light emitting device 201, the reflected excitation light E1rb, the reflected excitation light E2ra, and the fluorescence F2r are lost; and the luminous efficiency of the light emitting device 201 decreases.

The first wavelength selection layer 30 is transmissive to the excitation light E1. Thereby, for example, the incidence efficiency of the excitation light E1 on the substrate 40 becomes high. For example, the light amount of the reflected excitation light E1rb is less than the light amount of the reflected excitation light E1ra.

The first wavelength selection layer 30 is reflective to the fluorescence F2rb and the fluorescence F2t. Thereby, for example, unlike the fluorescence F2t, the fluorescence F2rb is not lost and is extracted to the external environment. Thereby, the loss of the light is less in the light emitting device 201 than in the light emitting device 200.

FIG. 11C is a schematic view showing a light emitting device 202 according to the embodiment. The light emitting unit 10 (not shown), the wavelength conversion layer 20, the substrate 40, and the reflective metal film 45 are provided in the light emitting device 202. The configuration described in regard to the light emitting device 110 is applicable to these components. The light emitting device 202 corresponds to a light emitting device in which the reflective metal film 45 is provided in the light emitting device 200.

In the light emitting device 202 as well, the excitation light E1 is emitted from the light emitting unit 10. Similarly to the description of the light emitting device 200, the transmitted excitation light E1t, the reflected excitation light E1ra, the reflected excitation light E2ra, the fluorescence F1, and the fluorescence F2t are produced in the light emitting device 202 as well. In the light emitting device 202, a portion of the excitation light E1 travels through the substrate 40, is incident on the wavelength conversion layer 20, and is reflected by the wavelength conversion layer 20. A portion (a reflected excitation light E2rc) of the excitation light E1 that is reflected by the wavelength conversion layer 20 travels in the direction toward the light emitting unit 10 and is incident on the reflective metal film 45. The reflected excitation light E2rc that is incident on the reflective metal film 45 is reflected by the reflective metal film 45, travels through the substrate 40 in the direction of the wavelength conversion layer 20, and is extracted to the external environment.

In the light emitting device 202 as well, fluorescence F2rc that is emitted from the wavelength conversion layer 20 travels, for example, in the direction toward the light emitting unit 10 and propagates through the substrate 40. The fluorescence F2rc is reflected by the reflective metal film 45, travels through the substrate 40 in the direction of the wavelength conversion layer 20, and is extracted to the external environment.

In the light emitting device 202, for example, the reflected excitation light E1ra, the reflected excitation light E2ra, and the fluorescence F2t are lost; and the luminous efficiency of the light emitting device 202 decreases.

For example, unlike the fluorescence F2r, the fluorescence F2rc is not lost and is extracted to the external environment. For example, unlike the reflected excitation light E2ra, the reflected excitation light E2rc is not lost and is extracted to the external environment. Thereby, the loss of the light is less in the light emitting device 202 than in the light emitting device 200.

FIG. 11D is a schematic view showing a light emitting device 203 according to the embodiment. The light emitting unit 10 (not shown), the wavelength conversion layer 20, the substrate 40, the first wavelength selection layer 30, and the reflective metal film 45 are provided in the light emitting device 203. The configuration described in regard to the light emitting device 110 is applicable to these components. The light emitting device 203 corresponds to a light emitting device in which the first wavelength selection layer 30 and the reflective metal film 45 are provided in the light emitting device 200.

Similarly to the description of the light emitting devices 200 to 202, the transmitted excitation light E1t, the reflected excitation light E1rb, the reflected excitation light E2ra, the reflected excitation light E2rc, the fluorescence F1, the fluorescence F2rb, and the fluorescence F2rc are produced in the light emitting device 203 as well. For example, in the light emitting device 203, the reflected excitation light E1rb and the reflected excitation light E2ra are lost; and the luminous efficiency of the light emitting device 203 decreases.

For example, in the light emitting device 203, the light amount of the reflected excitation light E1rb is less than the light amount of the reflected excitation light E1ra. The reflected excitation light E2rc, the fluorescence F2rc, and the fluorescence F2rb are not lost and are extracted to the external environment, unlike the reflected excitation light E2ra and F2r and the fluorescence F2t. Thereby, the loss of the light is less in the light emitting device 203 than in the light emitting devices 200 to 202. The light emitting device 203 is a highly efficient light emitting device.

FIG. 11E is a schematic view showing a light emitting device 204 according to the embodiment. The light emitting unit 10 (not shown), the wavelength conversion layer 20, the substrate 40, the first wavelength selection layer 30, the second wavelength selection layer 31, and the reflective metal film 45 are provided in the light emitting device 204. The configuration described in regard to the light emitting device 111 is applicable to these components. The light emitting device 204 corresponds to a light emitting device in which the first wavelength selection layer 30, the second wavelength selection layer 31, and the reflective metal film 45 are provided in the light emitting device 200.

Similarly to the description of the light emitting devices 200 to 203, the transmitted excitation light E1t, the reflected excitation light E1rb, the reflected excitation light E2rc, the fluorescence F1, the fluorescence F2rb, and the fluorescence F2rc are produced in the light emitting device 204 as well.

The second wavelength selection layer 31 is provided in the light emitting device 204. The second wavelength selection layer 31 is, for example, transmissive to the excitation light E1. Thereby, for example, the light that travels through the substrate 40 and is incident on the wavelength conversion layer 20 is not easily reflected by the wavelength conversion layer 20. The reflected excitation light E2ra such as that of the light emitting device 203 is not produced easily. The loss of the light is less in the light emitting device 204 than in the light emitting devices 200 to 203. The light emitting device 204 is a highly efficient light emitting device.

According to the embodiment, a highly efficient light emitting device can be provided.

In the specification, “nitride semiconductor” includes all compositions of semiconductors of the chemical formula

BₓIn_{y}Al_{z}Ga_{1-x-y-z}N (0≦x≦1, 0≦y≦1, 0≦z≦1, and x+y+z≦1) for which the composition ratios x, y, and z are changed within the ranges respectively. “Nitride semiconductor” further includes group V elements other than N (nitrogen) in the chemical formula recited above, various elements added to control various properties such as the conductivity type and the like, and various elements included unintentionally.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, embodiments of the invention are described with reference to specific examples. However, the embodiments of the invention are not limited to these specific examples. For example, one skilled in the art may similarly practice the invention by appropriately selecting specific configurations of components such as the light emitting unit, the wavelength conversion layer, the first wavelength selection layer, the second wavelength selection layer, the substrate, the mounting member, the reflective metal film, etc., from known art; and such practice is within the scope of the invention to the extent that similar effects can be obtained. Further, any two or more components of the specific examples may be combined within the extent of technical feasibility and are included in the scope of the invention to the extent that the purport of the invention is included.

Moreover, all light emitting devices practicable by an appropriate design modification by one skilled in the art based on the light emitting devices described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A light emitting device, comprising:
a light emitting unit to emit a first light having a first peak wavelength;
a first wavelength selection layer being transmissive to the first light and having a first reflectance with respect to the first peak wavelength; and
a wavelength conversion layer absorbing at least a portion of the first light passed through the first wavelength selection layer, the wavelength conversion layer emitting a second light having a second peak wavelength longer than the first peak wavelength,
the first wavelength selection layer having a second reflectance with respect to the second peak wavelength, the second reflectance being higher than the first reflectance.

2. The device according to claim 1, wherein a first transmittance of the first wavelength selection layer with respect to the first peak wavelength is higher than a second transmittance of the first wavelength selection layer with respect to the second peak wavelength.

3. The device according to claim 1, wherein
a first transmittance of the first wavelength selection layer with respect to the first peak wavelength is 80% or more, and
the second reflectance of the first wavelength selection layer to the second peak wavelength is 80% or more.

4. The device according to claim 1, wherein
the first wavelength selection layer includes a plurality of first optical layers and a plurality of second optical layers stacked alternately in a direction from the light emitting unit toward the wavelength conversion layer, and
refractive indexes of the plurality of first optical layers are different from refractive indexes of the plurality of second optical layers.

5. The device according to claim 4, wherein
each of the plurality of first optical layers includes a first material, the first material being at least one selected from an oxide and a nitride, the oxide including at least one selected from Si, Ta, Hf, Zr, and Mg, the nitride including at least one selected from Si, Ta, Hf, Zr and Mg,
each of the plurality of second optical layers includes a second material different from the first material, the second material being at least one selected from an oxide and a nitride, the oxide including at least one selected from Si, Ta, Hf, Zr and Mg, the nitride including at least one selected from Si, Ta, Hf, Zr and Mg.

6. The device according to claim 4, wherein
a thickness of each of the plurality of first optical layers is not less than 30 nanometers and not more than 200 nanometers, and
a thickness of each of the plurality of second optical layers is not less than 30 nanometers and not more than 200 nanometers.

7. The device according to claim 1, wherein
the first peak wavelength is less than 500 nanometers, and
the second peak wavelength is 500 nanometers or more.

8. The device according to claim 1, further comprising a substrate provided between the first wavelength selection layer and the wavelength conversion layer, the substrate being transmissive to the first light and the second light.

9. The device according to claim 8, further comprising a second wavelength selection layer provided between the wavelength conversion layer and the substrate, the second wavelength selection layer being transmissive to the first light and reflective to the second light.

10. The device according to claim 8, wherein
the first wavelength selection layer has a first surface on the light emitting unit side and a first side surface intersecting the first surface, the first surface including a first region and a second region,
the first region overlaps the light emitting unit when projected onto a plane intersecting a first direction from the light emitting unit toward the wavelength conversion layer,
the second region does not overlap the light emitting unit when projected onto the plane,
the substrate has a second side surface intersecting the plane, and
the device further includes a reflective metal film contacting at least a portion of at least one selected from the first side surface, the second side surface and the second region.

11. The device according to claim 10, wherein a reflectance of the reflective metal film to the first light is higher than a transmittance of the reflective metal film for the first light and higher than an absorptance of the reflective metal film for the first light.

12. The device according to claim 10, wherein the reflective metal film includes at least one selected from Al and Ag.

13. The device according to claim 10, further comprising a mounting member covering at least a portion of at least one selected from the first side surface, the second side surface and the second region.

14. The device according to claim 13, wherein the mounting member includes at least one selected from Al and Cu.

15. The device according to claim 8, wherein a surface area of the substrate is greater than a surface area of the light emitting unit when projected onto a plane intersecting a first direction from the light emitting unit toward the wavelength conversion layer.

16. The device according to claim 15, wherein the surface area of the substrate is not less than twice the surface area of the light emitting unit when projected onto the plane.

17. The device according to claim 8, wherein the substrate includes a sapphire substrate.

18. The device according to claim 8, wherein a thickness of the substrate is not less than 50 micrometers and not more than 1 millimeter.

19. The device according to claim 1, wherein the light emitting unit includes a semiconductor light emitting element to emit the first light.

20. The device according to claim 19, wherein the semiconductor light emitting element includes a light emitting diode.
